(19) United States
(12) Patent Application Publication
(10) Pub. No.: US 2014/0272688 A1
(43) Pub. Date: Sep. 18, 2014

(54) GRAYSCALE LITHOGRAPHY OF PHOTO DEFINABLE GLASS

(71) Applicant: PHOTRONICS, INC., (US)

(72) Inventor: Brian W. DILLION, Carrollton, TX (US)

(73) Assignee: PHOTRONICS, INC., Brookfield, CT (US)

(21) Appl. No.: 13/837,299

(22) Filed: Mar. 15, 2013

(51) Int. Cl. G03F 7/20

(52) U.S. Cl. CPC G03F 7/20
USPC 430/13; 430/325

(57) ABSTRACT

A method for forming a three-dimensional microstructure includes providing a photosensitive glass substrate; exposing the photosensitive glass substrate to energy through a continuous tone, variable transmission photomask so as to form opaque portions in the photosensitive glass substrate, each of the opaque portions having one of a variety of depths extending through the entire thickness of the photosensitive glass substrate; and removing the opaque portions so as to form three-dimensional features in the photosensitive glass substrate.

### FIELD OF THE INVENTION

The present invention relates to three-dimensional microstructures and methods of manufacturing three-dimensional microstructures.

### SUMMARY OF THE INVENTION

Conventional optical lithography techniques used for fabricating integrated circuits have been adapted to manufacture three-dimensional microstructures, such as microarrays, microfluidic devices, titer plates, microelectromechanical systems (MEMS) and three-dimensional glass structures. In conventional optical lithography, a fully resolved pattern is etched into a binary photomask and transferred to a wafer by exposing the wafer through an exposure tool (e.g., stepper). More particularly, binary photomasks are typically comprised of a substantially transparent substrate (e.g., quartz) and an opaque layer (e.g., chrome) in which the pattern to be transferred is etched. It is also known that other layers may be included on the photomask, including, for example, an antireflective layer (e.g., chrome oxide). The photoresist in the substrate on the integrated circuit being processed is then developed and either the exposed or unexposed portions are removed. Thereafter, the material on the substrate is etched in the areas where the photoresist is removed. An example of the technology involved in manufacturing a traditional binary photomask (e.g., chrome-on-quartz) and its use to manufacture integrated circuits is disclosed in, for example, U.S. Pat. No. 6,406,818.

It is known to use a photosensitive glass substrate to form a three-dimensional microstructure. Photosensitive glass, also called photodefinable glass, allows for the formation of microstructures in the glass without the use of photoresist. In particular, photosensitive glass, when exposed to UV light, then baked at a certain temperature and duration, transforms into a ceramic material (crystalline-phase lithium metasilicate). The ceramic material is much more active for reaction with a hydrofluoric acid (HF) etchant than the amorphous glass. Thus, according to conventional methods, different microstructures can be created in a top-down approach by exposing portions of the photosensitive glass to UV light through a binary photomask.

A problem associated with the conventional method of forming a three-dimensional structure in photosensitive glass substrates is that the exposed portions are transformed into opaque ceramic material through the thickness of the substrate. Depending on the desired feature depth, the etching step will only remove a certain percentage of the entire exposed portion, resulting in opaque portions remaining in the substrate. Particularly in the case of microfluidic applications, these opaque portions are undesirable. Another problem associated with the conventional method is that the remaining ceramic portions will result in increased autofluorescence, which interferes with detection of fluorescent signals.

### BRIEF DESCRIPTION OF THE DRAWINGS

The features and advantages of the present invention will be more fully understood with reference to the following, detailed description of an illustrative embodiment of the present invention when taken in conjunction with the accompanying figures, wherein:

FIG. 1 is a process diagram illustrating a method of manufacturing a three-dimensional microstructure according to an exemplary embodiment of the present invention; and

FIGS. 2A, 2B, 2C, and 2D are respective first, second, third, and fourth sequential cross sectional views of a process of creating a three-dimensional microstructure according to an exemplary embodiment of the present invention.

### DETAILED DESCRIPTION OF EMBODIMENTS OF THE PRESENT INVENTION

Various exemplary embodiments of the present invention are directed to a method of forming three-dimensional structures in a photosensitive glass substrate. In particular, according to exemplary embodiments, grayscale lithography techniques are used to partially expose portions of the photosensitive glass substrate to UV light so as to control the amount of substrate that is converted to ceramic material as a result of the exposure. The use of grayscale lithography allows for the formation of through-glass vias (TGVs) where ceramic through-conversion is full (100%), as well as the formation of other areas where the ceramic conversion is less than 100% (e.g., 0%, 10%, 20%, 50%, etc.). Thus, microfluidic and other types of three-dimensional microstructures can be formed with, for example, TGVs, channels and sub-features within the channels, with a single exposure.

According to exemplary embodiments of the present invention, any suitable grayscale lithography technique may be used to form three-dimensional structures in a photosensitive glass substrate. In this regard, it is known to use a continuous tone pattern on a photomask (e.g., chrome-on-glass) instead of a binary, fully resolved mask pattern to yield a continuous tone intensity through the photomask during image formation. One type of continuous tone, variable transmission photomask is commonly known as a binary half tone (“BHT”) photomask. BHT photomasks use two levels of gray tones (e.g., 0% transmissive and 100% transmissive). Another type of continuous tone, variable transmission photomask is known as a gray scale photomask, which uses varying levels of transmission of light through the photomask (e.g., 0%, 50%, 100%, etc.). By using these types of variable transmission photomasks, a three-dimensional structure can be formed in the photosensitive glass substrate through the use of a continuous tone pattern.

BHT photomasks are typically designed to have sub-resolution features that partially transmit exposure source light intensity based on feature modulation in width and pitch. In this regard, a BHT photomask layout may be designed for microscopic surfaces by dividing the patterned area of the photomask into pixels and sub-pixels (commonly referred to as “sub-pixelation”) which define areas on the mask through which light is to be transmitted. The sub-pixels defining the BHT photomask pattern are designed to be smaller than the resolution of the exposure tool being used so that a gray scale image can be created on the photosensitive glass substrate. An example of a BHT photomask that may be used in the present invention is disclosed in U.S. Pat. No. 6,828,068, the contents of which are incorporated herein by reference in their entirety.

FIG. 1 shows a flowchart describing a method for manufacturing a three-dimensional microstructure according to exemplary embodiments. FIG. 2A-2D show a series of diagrams illustrating a process of creating a three-dimensional microstructure according to exemplary embodiments. Any type of three-dimensional microstructure may be formed using the processes described herein, including, for example, microarrays, microfluidic devices, titer plates, microelectromechanical systems (MEMS) and three-dimensional glass structures.

Referring to FIGS. 1 and 2A, in step 102, a suitable substrate 10 is provided. In this regard, various exemplary embodiments of the present invention relate to three-dimensional microstructures manufactured from the substrate 10. Thus, the substrate 10 may have one or more layers that are substantially transparent. The substrate 10 may be made of photosensitive glass, such as, for example, APEX™ Glass, produced by Life BioScience Inc. of Albuquerque, N. Mex., USA, and Foturan™ or Zerodur™, both produced by Schott Glass Corp. of Mainz, Germany. In exemplary embodiments, wafers of photosensitive glass having a diameter within the range of 100 mm to 150 mm and a thickness of approximately 0.5 mm to over 4 mm, may be used. However, other sized wafers of photosensitive glass may also be used depending on application or need. For example, in exemplary embodiments, microscope slide sized wafers, such as, for example wafers ranging in size from approximately 25×76×1 mm to 25×76×0.5 mm may be used.

In step 104, the obtained substrate 10 is photo-patterned according to any suitable grayscale lithography process. For example, referring to FIG. 2A, a grayscale or BHT photomask 20 may be placed over the substrate 10 and exposed to a high-energy source, such as, for example, ultraviolet (UV) light. In exemplary embodiments involving the use of APEX™ Glass, for example, a 310 nm wavelength energy source may be appropriate. However, it should be appreciated that any other suitable wavelength may be used. Formation of channels on APEX glass and/or related materials are described in more detail in U.S. patent application Ser. Nos. 12/058,608 and 12/058,588, the disclosures of which are incorporated herein by reference in their entireties

Referring to FIG. 1, in step 106, according to exemplary embodiments, the exposed substrate 10 may be exposed to heat, such as by baking. While the heat application may be done through a furnace or oven, in various exemplary embodiments other heat sources may be used to apply heat to the substrate. The baking process may be done once, or multiple times at different temperatures for different lengths of time. In embodiments where APEX™ glass is the provided substrate, the baking process may be made up of two steps. The first step may include baking the substrate in an oven at a first temperature, such as, for example 500° C. for a period of time, such as, for example, 75 minutes. The next step may be baking the substrate at a higher temperature, such as 575° C. for another period of time, such as, for example, 75 minutes.

Referring to FIG. 2B, in exemplary embodiments, the heat 12 may transform UV exposed regions of the substrate 10 into altered portions 14. For example, the heating may transform exposed regions of the APEX™ glass or any other similar material into a substantially opaque ceramic material. However, the portions of the substrate 10 that are transformed into ceramic material are controlled by modulating the exposure light. For example, as previously described, grayscale lithography techniques may be used or the time and/or dose of exposure light may be controlled using direct write tools. Thus, altered portions 14 of various depths and/or widths can be formed in the substrate 10 in a single process flow (i.e., without requiring subsequent exposure steps to obtain microstructures of varying feature depth). In exemplary embodiments, altered portions 14 of the substrate 10 may have varying depths through the substrate 10, such as, for example, depths ranging from 0% to 100% through the entire thickness of the substrate 10, depending on the modulated exposure. For example, the altered portions 14 may extend 10%, 20%, 25%, 50%, 75%, or any other percentage through the entire thickness of the substrate 10. Any portions of the substrate 10 below the altered portions 14 are unaltered by the exposure and thus remain substantially transparent.

In step 108, the baked substrate 10 may be subjected to an etching process. FIG. 2C, for example, shows a UV photo-patterned and baked substrate 10 having altered portions 14 subjected to a wet etch 16. However, it should be appreciated that any suitable etching process may be used, such as, for example, a dry etch. Suitable wet etchants include, for example, hydrofluoric acid (HF). In regards to the shallower altered portions 14, the larger amount of glass remaining underneath results in a reduced etch rate as compared to the etch rate for deeper altered portions 14, which have a less amount of glass underneath. The differences in etch rates between the shallow and deep altered portions 14 allows for all of the altered portion 14 to be removed in a single etch step.

Referring to FIG. 2D, as a result of etching, channels 18 may be formed in the substrate 10. The dimensions of the channels 18 may depend on the parameters of photo-pattern, UV exposure, baking and etching processes. For example, the channels 18 may be formed with various dimensions, with the height of each channel 18 ranging from approximately 100 nm to 1 mm. In other words, the channel height may be only very shallow with respective to the substrate 10, or the channel 18 may form through the substrate 10 to form a TGV. The width of each channel 16 may range from approximately 1 um to 500 um.

Now that embodiments of the present invention have been shown and described in detail, various modifications and improvements thereon will become readily apparent to those skilled in the art. Accordingly, the spirit and scope of the present invention is to be construed broadly and not limited by the foregoing specification.

What is claimed is:

1. A method for forming a three-dimensional microstructure, comprising:
providing a photosensitive glass substrate;
exposing the photosensitive glass substrate to energy through a continuous tone, variable transmission photomask so as to form opaque portions in the photosensitive glass substrate, each of the opaque portions having one of a variety of depths extending through the entire thickness of the photosensitive glass substrate; and
removing the opaque portions so as to form three-dimensional features in the photosensitive glass substrate.

2. The method of claim 1, wherein the photosensitive glass substrate comprises photosensitive glass selected from the group consisting of: Foturan™ and APEX™ glass.

3. The method of claim 1, wherein the continuous tone, variable transmission photomask is a binary halftone photomask.

4. The method of claim 1, wherein the continuous tone, variable transmission photomask is a grayscale photomask.

5. The method of claim 1, wherein the energy is in the form of UV light.

6. The method of claim 1, wherein the variety of depths are within the range of 0% to 100%.

7. The method of claim 1, wherein the variety of depths comprise 0%, 20%, 25%, 50%, 70%, 75% and 100%.

8. The method of claim 1, further comprising the step of baking the photosensitive glass substrate.

9. The method of claim 1, wherein the step of baking comprises heating the photosensitive glass substrate to a temperature within the range of 450° C. to 550° C.

10. The method of claim 1, wherein the step of removing comprises etching the photosensitive glass substrate.

11. The method of claim 10, wherein the etching is performed using a wet etchant.

12. The method of claim 10, wherein the etching is performed using a dry etchant.

13. The method of claim 1, wherein the three-dimensional features comprise a type selected from the group consisting of: channels, through-hole vias, and channel sub-features.

14. The method of claim 1, wherein the three-dimensional microstructure comprises one or more microstructures selected from the group consisting of: microarrays, microfluidic devices and titer plates.

15. A three-dimensional microstructure formed according to the method of claim 1.
